(19) United States
(12) Patent Application Publication
(10) Pub. No.: US 2024/0234530 A1
(43) Pub. Date: Jul. 11, 2024

(54) FIELD EFFECT TRANSISTOR WITH STRAINED CHANNELS AND METHOD

(71) Applicant: Taiwan Semiconductor Manufacturing Co., Ltd., Hsinchu (TW)

(72) Inventors: Chun-Hsiung TSAI, Hsinchu (TW); Yu-Ming LIN, Hsinchu (TW); Kuo-Feng YU, Hsinchu (TW); Yu-Ting LIN, Hsinchu (TW); Ming-Te CHEN, Hsinchu (TW); Yi-Hsiu HUANG, Hsinchu (TW)

(21) Appl. No.: 18/330,229

(22) Filed: Jun. 6, 2023

Related U.S. Application Data
(60) Provisional application No. 63/486,641, filed on Feb. 23, 2023.
(60) Provisional application No. 63/479,341, filed on Jan. 10, 2023.

(51) Int. Cl. H01L 29/423; H01L 29/06; H01L 29/66; H01L 29/775; H01L 29/786

(52) U.S. Cl. CPC H01L 29/42392; H01L 29/0649; H01L 29/0673; H01L 29/66439; H01L 29/66545; H01L 29/66553; H01L 29/775; H01L 29/78696

(57) ABSTRACT

A device includes: a stack of nanostructure channels over a substrate; a gate structure wrapping around the stack; and a source/drain region on the substrate. The source/drain region includes: a first epitaxial layer in direct contact with the channels; and a second epitaxial layer on the first epitaxial layer, the second epitaxial layer having higher germanium concentration than the first epitaxial layer. The device further includes a bottom isolation structure between the source/drain region and the substrate, the bottom isolation structure being a dielectric layer that is in direct contact with the source/drain region.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrammatic cross-sectional side views of a portion of an IC device fabricated according to embodiments of the present disclosure.

FIGS. 2A-17 are views of an IC device of at various stages of fabrication according to embodiments of the present disclosure.

FIGS. 18A-19F are views of an IC device according to various aspects of the present disclosure.

FIG. 20 is a flowchart illustrating a method of fabricating a semiconductor device according to various aspects of the present disclosure.

FIG. 21 is a view of an IC device according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to field-effect transistors (FETs), such as planar FETs, three-dimensional fin-line FETs (FinFETs), or nanostructure devices. Examples of nanostructure devices include gate-all-around (GAA) devices, nanosheet FETs (NSFETs), nanowire FETs (NWFETs), and the like. In advanced technology nodes, dimension scaling can lead to difficulties forming contacts and vias to the gate, source and drain electrodes of the FETs.

A dual flexible bottom insulator (FBI) is generally designed to be placed on N/P metal oxide semiconductor (MOS) source/drain (S/D) bottom of nanostructure transistors, such as gate-all-around (GAA) transistors. The dual FBI structure prevents bottom parasitic transistor leakage current while also reducing parasitic capacitance (e.g., effective capacitance Ceff), which is beneficial for device (e.g., ring oscillator) performance improvement. In some GAA transistor structures, germanium-free epitaxial layers (e.g., Si:As or Si:P) are formed in NFET source/drain regions, without using an FBI structure.

By using the dual FBI structure in a GAA transistor, a compressive stressor of germanium-containing epitaxial layers (e.g., SiGe:P or SiGe:As) in N-type field effect transistor (NFET) source/drain regions can become a sidewall (SW) deposition dominated film. The side-wall deposition compressive stressor can generate a tensile stress on NFET silicon nanosheets, which can induce a corresponding tensile strain in the Si nanosheets, which may increase NFET channel carrier mobility. A wide range of tensile stress tuning can be achieved for N-type channels. The flexible-bottom-isolation (FBI) approach eliminates the Si substrate to Ge lattice mismatch.

The nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure transistor structure.

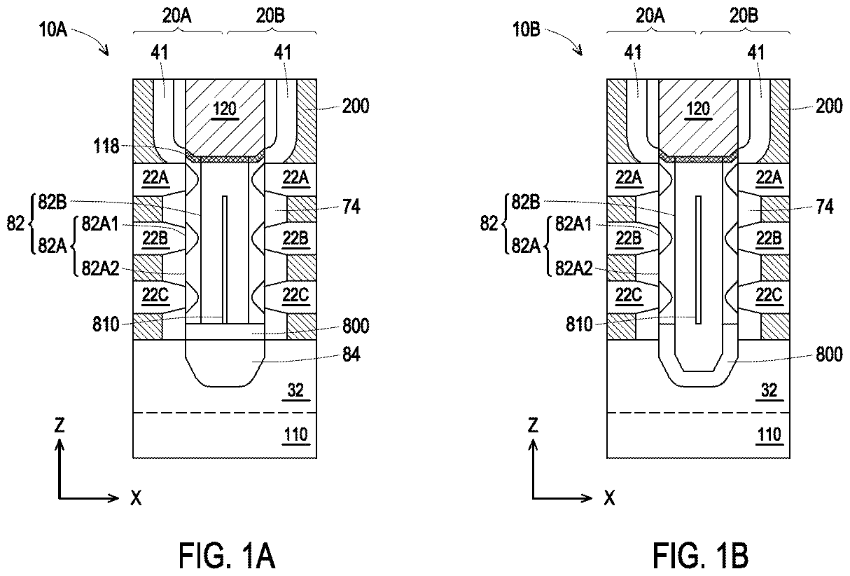

FIGS. 1A and 1B illustrate diagrammatic cross-sectional side views of portions of IC devices 10A, 10B fabricated according to embodiments of the present disclosure, where the IC devices 10A, 10B include nanostructure devices 20A, 20B. Certain features may be removed from view intentionally in the views of FIGS. 1A and 1B for simplicity of illustration.

FIG. 1A shows a portion of IC device 10A including nanostructure devices 20A, 20B. The nanostructure devices 20A, 20B may include at least an N-type FET (NFET), a P-type FET (PFET), or both, in some embodiments. The IC device 10A may include transistors having different threshold voltages based on their function in the IC device. For example, input/output (IO) transistors typically have the highest threshold voltages, core logic transistors typically have the lowest threshold voltages, and a third threshold voltage between that of the IO transistors and that of the core logic transistors may also be employed for certain other functional transistors, such as static random access memory (SRAM) transistors. Some circuit blocks within the IC device 10A may include two or more NFETs and/or PFETs of two or more different threshold voltages.

Referring to FIG. 1A, the nanostructure devices 20A, 20B are formed over and/or in a substrate 110, and generally include gate structures 200 straddling and/or wrapping around semiconductor channels 22A, 22B, 22C, alternately referred to as “nanostructures,” located over semiconductor fin 32 protruding from, and separated by, isolation structures (e.g., shallow-trench isolation structures; not shown). The channels 22A-22C are abutted by respective source/drain regions 82. Each gate structure 200 controls current flow between source/drain regions 82 through the channels 22A-22C. The channels 22A-22C are optionally over the fin 32. In some embodiments, the fin 32 and the substrate 110 are not present, for example, when the fin 32 and the substrate 110 are removed in a process that forms a backside interconnect structure (e.g., including a backside power rail). Source/drain region(s) may refer to a source or a drain, individually or collectively dependent upon the context.

The channels 22A-22C include a semiconductive material, for example silicon or a silicon compound, such as silicon germanium, or the like. In some embodiments, the fin structure 32 includes silicon. The channels 22A-22C are nanostructures (e.g., having sizes that are in a range of a few nanometers) and may also each have an elongated shape and extend in the X-direction. In some embodiments, the channels 22A-22C each have a nano-wire (NW) shape, a nano-sheet (NS) shape, a nano-tube (NT) shape, or other suitable nanoscale shape. The cross-sectional profile of the channels 22A-22C may be rectangular, round, square, circular, elliptical, hexagonal, or combinations thereof.

In some embodiments, the lengths (e.g., measured in the X-axis direction) of the channels 22A-22C may be different from each other, for example due to tapering during a fin etching process. In some embodiments, length of the channel 22A may be less than a length of the channel 22B, which may be less than length of the channel 22C. The channels 22A-22C each may not have uniform thickness, for example due to a channel trimming process used to expand spacing (e.g., measured in the Z-direction) between the channels 22A-22C to increase gate structure fabrication process window. For example, a middle portion of each of the channels 22A-22C may be thinner than the two ends of each of the channels 22A-22C. Such shape may be collectively referred to as a “dog-bone” shape. In FIGS. 1A and 1B, the ends of the channels 22A-22C are tapered and narrower than the middle portions of the channels 22A-22C.

In some embodiments, spacing between neighboring pairs of the channels 22A-22C (e.g., between the channel 22B and the channel 22A or the channel 22C) is in a range between about 8 nanometers (nm) and about 12 nm. In some embodiments, a thickness (e.g., measured in the Z-direction) of each of the channels 22A-22C is in a range between about 5 nm and about 8 nm. In some embodiments, a width (e.g., measured in the Y-axis direction, not shown in FIGS. 1A and 1B, orthogonal to the X-Z plane) of each of the channels 22A-22C is at least about 8 nm.

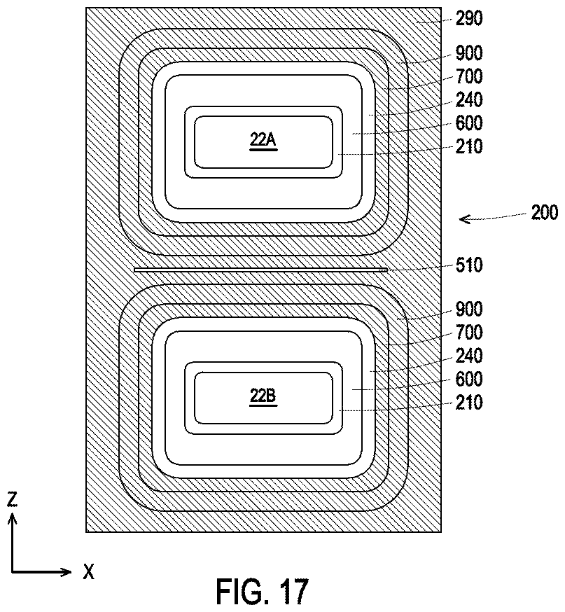

The gate structures 200 are disposed over and between the channels 22A-22C, respectively. In some embodiments, the gate structures 200 are disposed over and between the channels 22A-22C, which are silicon channels for N-type devices or silicon germanium channels for P-type devices. In some embodiments, the gate structures 200 include an interfacial layer (IL) 210, one or more gate dielectric layers 600, one or more work function tuning layers 900, and a metal fill layer 290, which are shown and described in greater detail with reference to FIG. 17.

The source/drain regions 82 may include SiB, SiGe, SiGeB, and may include dopants, such as Ge, Sb, B, or the like. In some embodiments, the source/drain regions 82 include silicon phosphorous (SiP; Si:P), silicon arsenic (SiAs, Si:As) or the like. In some embodiments, the source/drain regions 82 have width (e.g., in the Y-axis direction) in a range of about 0.5 nm to about 100 nm. In some embodiments, height of the source/drain regions 82 (e.g., in the Z-axis direction) is in a range of about 0.1 nm to about 100 nm. The height of the source/drain regions 82 may be measured from an interface between a respective source/drain region 82 and a dielectric layer 800 (or “FBI layer 800” or “bottom isolation structure 800”) on which it is disposed to a top of the source/drain region 82.

The nanostructure devices 20A, 20B may include gate or “sidewall” spacers 41 and inner spacers 74 that are disposed on sidewalls of the gate dielectric layer 600 and the IL 210. The inner spacers 74 are also disposed between the channels 22A-22C. The sidewall spacers 41 and the inner spacers 74 may include a dielectric material, for example a low-k material such as SiOCN, SION, SiN, SiCN or SiOC. In some embodiments, the sidewall spacers 41 may include one or more spacer layers. For example, as shown in FIGS. 1A and 1B, the sidewall spacers 41 include two spacer layers. In some embodiments, thickness of the inner spacers 74 (e.g., in the X-axis direction) is in a range of about 3 nm to about 10 nm. In some embodiments, thickness of the sidewall spacers 41 (e.g., in the X-axis direction) is in a range of about 3 nm to about 10 nm.

The nanostructure devices 20A, 20B include bottom isolation structures 800 that are beneath the source/drain regions 82. This bottom isolation structures 800 are formed at the bottom of source/drain region 82 cavities, and are beneficial to reduce volume of the source/drain regions 82, which reduces the effective capacitance. The bottom isolation structures 800 are or include SiN, SiCN, SiCON, SiOC, SiC, SiO or the like. Shape of the bottom isolation structures 800 can be a horizontal I-shape, a bowl shape, a dish shape, a U-shape, a V-shape or the like, and may be selected by an etching process for forming the source/drain regions 82. The bottom isolation structures 800 may have thickness that may range from about 1 nm to about 5 nm. The bottom isolation structures 800 may be formed by one or more conformal film deposition processes (e.g., a plasma-enhanced atomic layer deposition or “PEALD”) followed by a film treatment (e.g., etching back), and may be a conformal thin film that inherits the shape of the underlying structure on which it is formed. The film deposition may be implemented by a cyclic PEALD process with a reaction gas, such as dichlorosilane (DCS), and NH3/Ar plasma. The film treatment (e.g., etching) may be implemented by Ar/N2 plasma.

In FIG. 1A, a liner or “L0” layer 84 may be optionally disposed between the bottom isolation structure 800 and the substrate 110, the fin 32 or both. The liner layer 84 may be a silicon layer, in some embodiments. In FIG. 1B, the liner layer 84 is not present. When the liner layer 84 is present, the bottom isolation structure 800 may be a substantially horizontal thin layer, as shown in FIG. 1A. When the liner layer 84 is not present, the bottom isolation structure 800 may have a U-shaped or V-shaped profile, as shown in FIG. 1B, and may be in contact with the fin 32.

The source/drain regions 82 may include one or more epitaxial regions, such as a first epitaxial region 82A and a second epitaxial region 82B. The first epitaxial region 82A may be referred to as a first epitaxial or “L1” layer 82A, and may include first epitaxial sub-layers 82A1 in contact with the channels 22A-22B and a second epitaxial sub-layer 82A2 on the first epitaxial sub-layers 82A1. The second epitaxial region 82B may also be referred to as a second epitaxial or “L2” layer 82B, and is in contact with the second epitaxial sub-layer 82A2. A seam 810 may be present in the second epitaxial layer 82B. In some embodiments, the seam or void 810 has width in the X-axis direction that is less than 1 nm.

Each of the first epitaxial sub-layers 82A1, the second epitaxial sub-layer 82A2 and the second epitaxial layer 82B may be a germanium-containing epitaxial layer for NMOS transistors that is formed in an S/D trench. Sequential compressive SiGe:P or SiGe: As deposition allows the epitaxial growth mechanism to be sidewall (SW) growth instead of bottom-up growth (e.g., growth that begins from the fin 32 or the substrate 110). The bottom isolation structure 800 is provided at the bottom of the S/D trench, so SiGe:P or SiGe: As film formed at the bottom of the S/D trench may become amorphous and be removed during an etching process of the selective epitaxial growth. Sidewall SiGe:P or SiGe:As becomes crystalline and remains on the sidewalls, e.g., the channels 22A-22B and the inner spacers 74. The germanium-containing epitaxial layers for NMOS may be formed by multiple selective epitaxial growth processes (or so-called “cyclic deposition and etching processes”), which may include deposition operations and etching operations performed alternately or simultaneously. For SW-dominated grown SiGe:P or SiGe:As epitaxial films, although the epitaxial films still generate a compressive stress, the SW grown SiGe:P or SiGe:As films can exert tensile strain on the Si nanosheets 22A-22C instead of compressive strain. In some embodiments, tensile strain is greater on the nanosheet 22B than on the nanosheets 22A, 22C. Namely, nanosheets 22A, 22C on the periphery (e.g., nearer the top or bottom) of a vertical stack may have lower tensile strain than nanosheet(s) 22B in the middle of the vertical stack. For example, a nanosheet(s) at the center of the vertical stack may have the highest tensile strain, and tensile strain may decrease with increased distance from the center, where the “center” refers to the center of the vertical stack along the Z-axis direction.

In the L1 and L2 layers 82A, 82B, germanium concentration or “Ge %” (e.g., Ge/Si atomic ratio) may be lower than about 70%, and Ge % (Ge/Si atomic ratio) of the L1 layer(s) 82A is lower than Ge % (Ge/Si atomic ratio) of the L2 layer 82B. For example, the L1 layer 82A may have Ge % that may range from about 10% to about 50%, and the L2 layer 82B may have Ge % that may range from about 25% to about 70%. Atomic ratio of N-type dopants (e.g., As or P) to Si in the L1 and L2 layers 82A, 82B may be lower than about 10%, and atomic ratio of N-type dopants in the L1 layer 82A may be lower than that in the L2 layer 82B. For example, atomic ratio of N-type dopants in the L1 layer 82A may range from about 0.5% to about 4%, and atomic ratio of N-type dopants in the L2 layer may range from about 0.5% to about 8%. In some embodiments, N-type dopant concentration in the L1 layer 82A is in a range of about 2.5E20 to about 2E21 cm⁻³, and N-type dopant concentration in the L2 layer 82B is in a range of about 2.5E20 to about 4E21 cm⁻³. Thickness of each of the L1 and L2 layers 82A, 82B may be less than about 15 nm, and thickness of the L1 layer 82A may be less than that of the L2 layer 82B. As one non-limiting example, the L1 layer 82A may have Ge % of 15-50% and phosphide atomic ratio of 4-8%, and the L2 layer 82B may have Ge % of 25-50% and phosphide atomic ratio of 1-4%, and phosphide dopant concentration may be 5E20-2E21 cm⁻³. In another non-limiting example, the L1 layer 82A may have Ge % of 15-50% and arsenic atomic ratio of 2-6%, and the L2 layer 82B may have Ge % of 15-50% and arsenic atomic ratio of 0.5-6%, and arsenic dopant concentration may be 2.5E20-3E21 cm⁻³. Although two epitaxial layers 82A, 82B are illustrated in FIGS. 1A and 1B, number of the epitaxial layers is not limited thereto. In some embodiments, the number of the epitaxial layers in the source/drain region 82 can be three or more, or one.

The nanostructure devices 20A, 20B may include source/drain contacts 120 over one or more of the source/drain regions 82. The source/drain contacts 120 may include one or more liner layers and a core conductive layer (not separately illustrated in FIGS. 1A and 1B). A silicide layer 118 may also be formed between the source/drain regions 82 and the source/drain contacts 120, so as to reduce the source/drain contact resistance. In some embodiments, the silicide layer 118 is or includes one or more of nickel, cobalt, titanium, tantalum, platinum, tungsten, other noble metals, other refractory metals, rare earth metals or their alloys. For example, the silicide layer 118 may be TiSi, TiNiSi, NiSi, WSi, CoSi, MoSi, RuSi, or the like. In some embodiments, thickness of the silicide layer 118 (in the Z direction) is in a range of about 0.5 nm to about 10 nm, such as in a range of about 3 nm to about 10 nm. In some embodiments, height of the source/drain contacts 120 may be in a range of about 1 nm to about 100 nm, such as about 10 nm to about 100 nm.

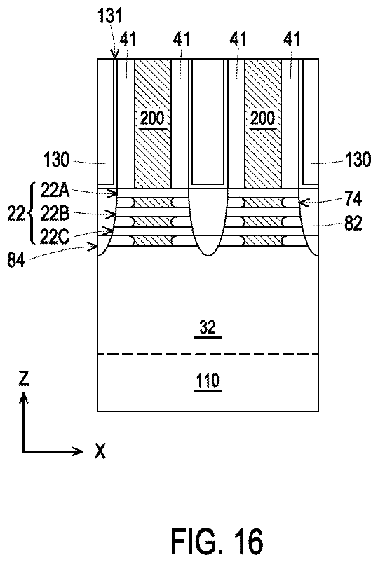

Although not shown in the views of FIGS. 1A and 1B, the nanostructure devices 20A, 20B include an interlayer dielectric (ILD) 130 and an etch stop layer 131 (see FIG. 16, for example). The ILD 130 provides electrical isolation between the various components of the nanostructure devices 20A, 20B discussed above, for example between the gate structures 200 and the source/drain contacts 120 therebetween. The etch stop layer 131 may be formed prior to forming the ILD 130, and may be positioned laterally between the ILD 130 and the sidewall spacers 41 and vertically between the ILD 130 and the source/drain regions 82. In some embodiments, the etch stop layer 131 is or includes SiN, SiCN, SiC, SiOC, SiOCN, HfO2, ZrO2, ZrAlOx, HfAlOx, HfSiOx, Al2O3, or other suitable material. In some embodiments, thickness of the etch stop layer 131 is in a range of about 1 nm to about 5 nm.

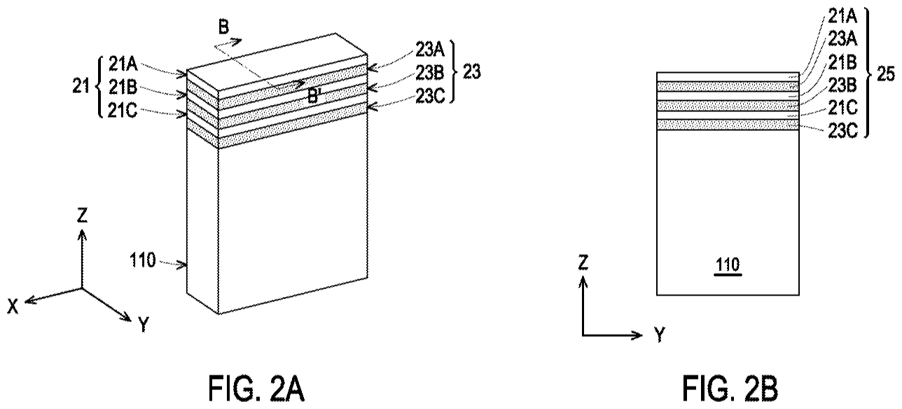

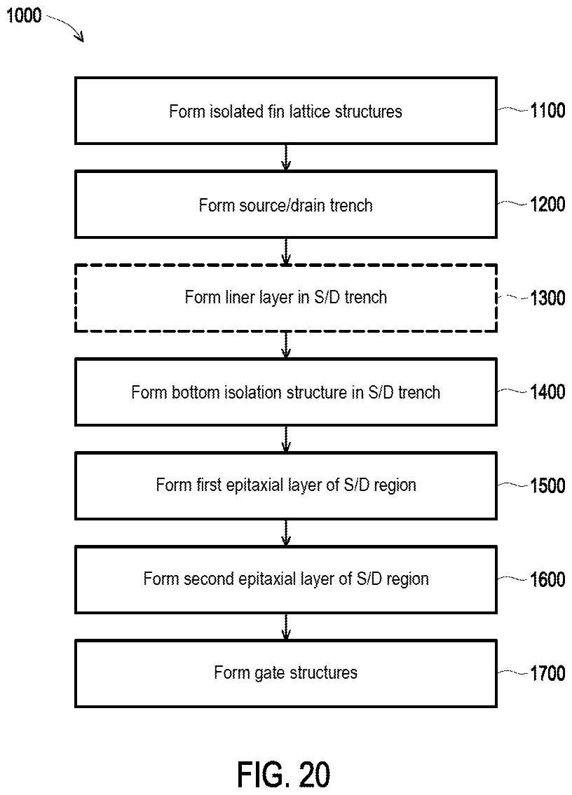

FIG. 20 illustrates a flowchart of a method 1000 for forming an IC device or a portion thereof from a workpiece, according to one or more aspects of the present disclosure. Method 1000 is merely an example and is not intended to limit the present disclosure to what is explicitly illustrated in method 1000. Additional acts can be provided before, during and after the method 1000 and some acts described can be replaced, eliminated, or moved around for additional embodiments of the methods. Not all acts are described herein in detail for reasons of simplicity. For example, operations that form source/drain contacts 120, a frontside interconnect structure, a backside interconnect structure, and the like may follow the method 1000. For example, act 1300 may be optional. For example, additional epitaxial layers may be formed after act 1600 and before act 1700. Method 1000 is described below in conjunction with fragmentary perspective and/or cross-sectional views of a workpiece, shown in FIGS. 2A-16, at different stages of fabrication according to embodiments of method 1000. For avoidance of doubt, throughout the figures, the X-axis direction is perpendicular to the Y-axis direction and the Z-axis direction is perpendicular to both the X-axis direction and the Y-axis direction. It is noted that, because the workpiece may be fabricated into a semiconductor device, the workpiece may be referred to as the semiconductor device as the context requires. The method 1000 may be used to form the devices 10A, 10B illustrated in FIGS. 1A, 1B and 18A-19F.

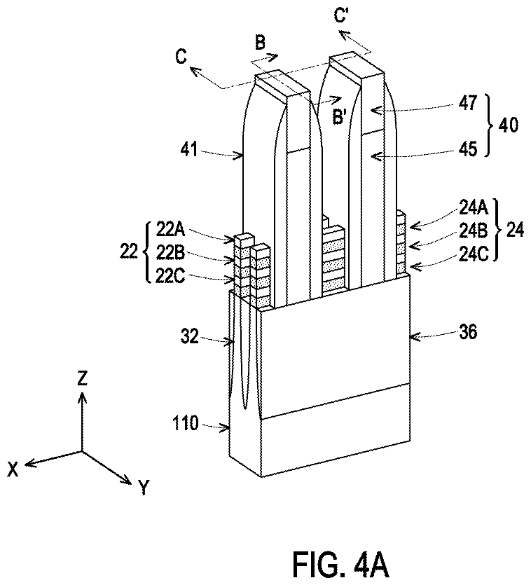

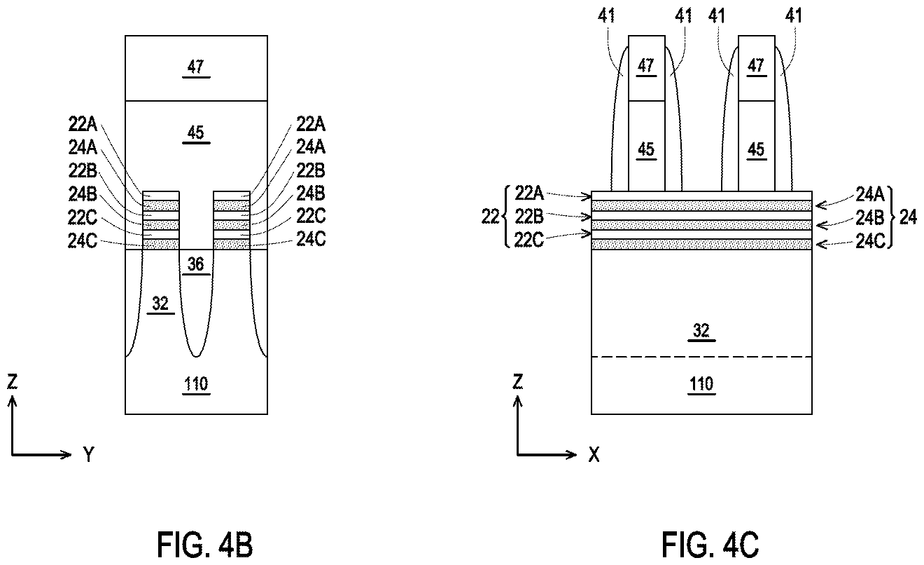

FIGS. 2A through 16 are perspective views and cross-sectional views of intermediate stages in the manufacturing of nanostructure devices, such as gate-all-around field-effect transistors (GAAFETs), in accordance with some embodiments. FIGS. 2A, 3A, 4A, 5A, 6A, 7A, 8A, 14A, and 15A illustrate perspective views. FIGS. 2B, 3B, 4B, 5B, 6B, 7B, 8B, 14B, and 15B illustrate reference cross-section B-B′ (gate cut) illustrated in FIGS. 2A, 3A, and 4A. FIGS. 4C, 5C, 6C, 7C, 9A-13B, 14C, 15C and 16 illustrate reference cross-section C-C′ (channel/fin cut) illustrated in FIG. 4A.

In FIG. 2A and FIG. 2B, a substrate 110 is provided. The substrate 110 may be a semiconductor substrate, such as a bulk semiconductor, or the like, which may be doped (e.g., with a p-type or an n-type dopant) or undoped. The semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

Further in FIG. 2A and FIG. 2B, a multi-layer stack 25 or “lattice” is formed over the substrate 110 of alternating layers of first semiconductor layers 21A, 21B, 21C (collectively referred to as first semiconductor layers 21) and second semiconductor layers 23A, 23B, 23C (collectively referred to as second semiconductor layers 23). In some embodiments, the first semiconductor layers 21 may be formed of a first semiconductor material suitable for n-type nanostructure devices, such as silicon, silicon carbide, or the like, and the second semiconductor layers 23 may be formed of a second semiconductor material suitable for p-type nanostructure devices, such as silicon germanium or the like. Each of the layers of the multi-layer stack 25 may be epitaxially grown using a process such as chemical vapor deposition (CVD), atomic layer deposition (ALD), vapor phase epitaxy (VPE), molecular beam epitaxy (MBE), or the like.

Three layers of each of the first semiconductor layers 21 and the second semiconductor layers 23 are illustrated. In some embodiments, the multi-layer stack 25 may include one or two each or four, five or more each of the first semiconductor layers 21 and the second semiconductor layers 23. Although the multi-layer stack 25 is illustrated as including a second semiconductor layer 23C as the bottommost layer, in some embodiments, the bottommost layer of the multi-layer stack 25 may be a first semiconductor layer 21.

Due to high etch selectivity between the first semiconductor materials and the second semiconductor materials, the second semiconductor layers 23 of the second semiconductor material may be removed without significantly removing the first semiconductor layers 21 of the first semiconductor material, thereby allowing the first semiconductor layers 21 to be patterned to form channel regions of nanostructure devices. In some embodiments, the first semiconductor layers 21 are removed and the second semiconductor layers 23 are patterned to form channel regions. The high etch selectivity allows the first semiconductor layers 21 of the first semiconductor material to be removed without significantly removing the second semiconductor layers 23 of the second semiconductor material, thereby allowing the second semiconductor layers 23 to be patterned to form channel regions of nanostructure devices.

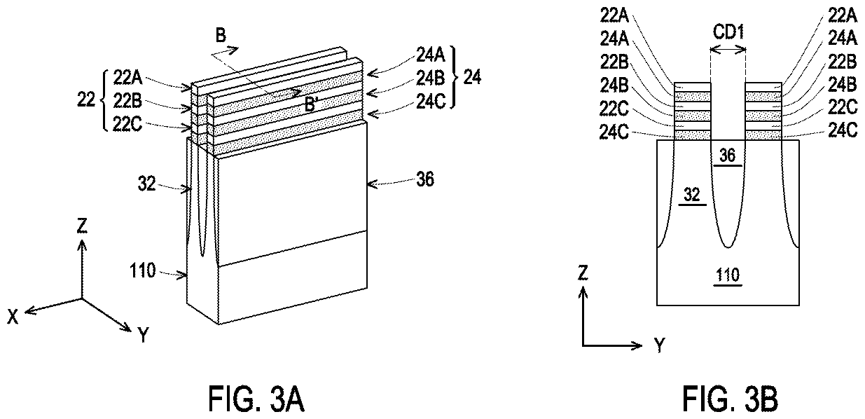

In FIGS. 3A and 3B, fins 32 are formed in the substrate 110 and nanostructures 22, 24 are formed in the multi-layer stack 25 corresponding to act 1100 of FIG. 20. In some embodiments, the nanostructures 22, 24 and the fins 32 may be formed by etching trenches in the multi-layer stack 25 and the substrate 110. The etching may be any acceptable etch process, such as a reactive ion etch (RIE), neutral beam etch (NBE), the like, or a combination thereof. The etching may be anisotropic. First nanostructures 22A-22C (also referred to as “channels” below) are formed from the first semiconductor layers 21, and second nanostructures 24A-24C are formed from the second semiconductor layers 23. Distance CD1 between adjacent fins 32 and nanostructures 22, 24 may be from about 18 nm to about 100 nm. A portion of the device 10A or the device 10B is illustrated in FIGS. 3A and 3B including two fins 32 for simplicity of illustration. The method 1000 illustrated in FIGS. 2A-16 may be extended to any number of fins, and is not limited to the two fins 32 shown in FIGS. 3A-16.

FIGS. 3A and 3B illustrate the fins 32 having tapered sidewalls, such that a width of each of the fins 32 and/or the nanostructures 22, 24 continuously increases in a direction towards the substrate 110. In such embodiments, each of the nanostructures 22, 24 may have a different width and be trapezoidal in shape. In other embodiments, the sidewalls are substantially vertical (non-tapered), such that width of the fins 32 and the nanostructures 22, 24 is substantially similar, and each of the nanostructures 22, 24 is rectangular in shape.

In FIGS. 3A and 3B, isolation regions 36, which may be shallow trench isolation (STI) regions, are formed adjacent the fins 32. The isolation regions 36 may be formed by depositing an insulation material over the substrate 110, the fins 32, and nanostructures 22, 24, and between adjacent fins 32 and nanostructures 22, 24. The insulation material may be an oxide, such as silicon oxide, a nitride, the like, or a combination thereof, and may be formed by high-density plasma CVD (HDP-CVD), flowable CVD (FCVD), the like, or a combination thereof. In some embodiments, a liner (not separately illustrated) may first be formed along surfaces of the substrate 110, the fins 32, and the nanostructures 22, 24. Thereafter, a fill material, such as those discussed above may be formed over the liner.

The insulation material undergoes a removal process, such as a chemical mechanical polish (CMP), an etch-back process, combinations thereof, or the like, to remove excess insulation material over the nanostructures 22, 24. Top surfaces of the nanostructures 22, 24 may be exposed and level with the insulation material after the removal process is complete. In some embodiments, one or more hard mask layers is present over the nanostructures 22, 24 to protect the nanostructures 22, 24 during the removal process that removes the excess insulation material over the nanostructures 22, 24. The hard mask layers may be exposed and level with the insulation material after the removal process is complete.

The insulation material is then recessed to form the isolation regions 36. After recessing, the nanostructures 22, 24 and upper portions of the fins 32 may protrude from between neighboring isolation regions 36. The isolation regions 36 may have top surfaces that are flat as illustrated, convex, concave, or a combination thereof. In some embodiments, the isolation regions 36 are recessed by an acceptable etching process, such as an oxide removal using, for example, dilute hydrofluoric acid (dHF), which is selective to the insulation material and leaves the fins 32 and the nanostructures 22, 24 substantially unaltered.

FIGS. 2A through 3B illustrate one embodiment (e.g., etch last) of forming the fins 32 and the nanostructures 22, 24. In some embodiments, the fins 32 and/or the nanostructures 22, 24 are epitaxially grown in trenches in a dielectric layer (e.g., etch first). The epitaxial structures may comprise the alternating semiconductor materials discussed above, such as the first semiconductor materials and the second semiconductor materials.

Further in FIG. 3A and FIG. 3B, appropriate wells (not separately illustrated) may be formed in the fins 32, the nanostructures 22, 24, and/or the isolation regions 36. Using masks, an n-type impurity implant may be performed in p-type regions of the substrate 110, and a p-type impurity implant may be performed in n-type regions of the substrate 110. Example n-type impurities may include phosphorus, arsenic, antimony, or the like. Example p-type impurities may include boron, boron fluoride, indium, or the like. An anneal may be performed after the implants to repair implant damage and to activate the p-type and/or n-type impurities. In some embodiments, in situ doping during epitaxial growth of the fins 32 and the nanostructures 22, 24 may obviate separate implantations, although in situ and implantation doping may be used together.

The fins 32 and the nanostructures 22, 24 may be patterned by any suitable method. For example, one or more photolithography processes, including double-patterning or multi-patterning processes, may be used to form the fins 32 and the nanostructures 22, 24. Generally, double-patterning or multi-patterning processes combine photolithography and self-aligned processes, allowing for pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fins 32.

In FIGS. 4A-4C, dummy (or “sacrificial”) gate structures 40 are formed over the fins 32 and/or the nanostructures 22, 24. A dummy or sacrificial gate layer 45 is formed over the fins 32 and/or the nanostructures 22, 24. The dummy gate layer 45 may be formed of materials that have a high etching selectivity versus the isolation regions 36. The dummy gate layer 45 may be a conductive, semiconductive, or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 45 may be deposited by physical vapor deposition (PVD), CVD, sputter deposition, or other techniques for depositing the selected material. A mask layer 47 is formed over the dummy gate layer 45, and may include, for example, silicon nitride, silicon oxynitride, or the like. In some embodiments, a gate dielectric layer (not illustrated for simplicity) is formed before the dummy gate layer 45 between the dummy gate layer 45 and the fins 32 and/or the nanostructures 22, 24.

A spacer layer or sidewall spacer 41 is formed over sidewalls of the mask layer 47 and the dummy gate layer 45. The spacer layer 41 is made of an insulating material, such as silicon nitride, silicon oxide, silicon carbo-nitride, silicon oxynitride, silicon oxy carbo-nitride, or the like, and may have a single-layer structure or a multi-layer structure including a plurality of dielectric layers, in accordance with some embodiments. The spacer layer 41 may be formed by depositing a spacer material layer (not shown) over the mask layer 47 and the dummy gate layer 45. Portions of the spacer material layer between dummy gate structures 40 are removed using an anisotropic etching process, in accordance with some embodiments.

FIGS. 4A-4C illustrate one process for forming the spacer layer 41. In some embodiments, the spacer layer 41 is formed alternately or additionally after removal of the dummy gate layer 45. In such embodiments, the dummy gate layer 45 is removed, leaving an opening, and the spacer layer 41 may be formed by conformally coating material of the spacer layer 41 along sidewalls of the opening. The conformally coated material may then be removed from the bottom of the opening corresponding to the top surface of the uppermost channel, e.g., the channel 22A, prior to forming an active gate, such as any of the gate structures 200.

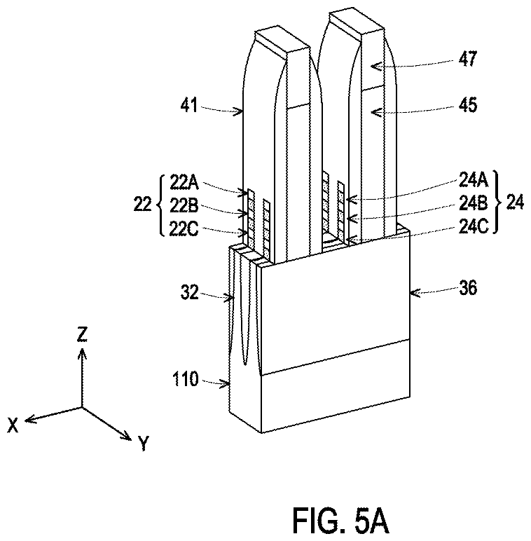

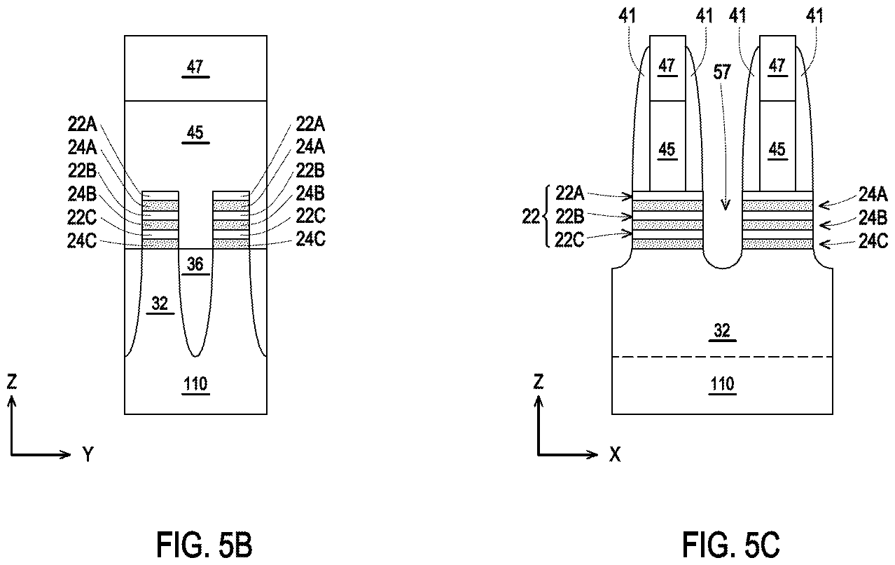

In FIGS. 5A-5C, corresponding to act 1200 of FIG. 20, source/drain trenches 57 are formed by performing an etching process that recesses the portions of protruding fins 32 and/or nanostructures 22, 24 that are not covered by dummy gate structures 40, resulting in the structure shown. The recessing may be anisotropic, such that the portions of fins 32 directly underlying dummy gate structures 40 and the spacer layer 41 are protected, and are not etched. The top surfaces of the recessed fins 32 may be substantially coplanar with the top surfaces of the isolation regions 36 as shown, in accordance with some embodiments. The top surfaces of the recessed fins 32 may be lower than the top surfaces of the isolation regions 36, in accordance with some other embodiments. FIG. 5C shows two vertical stacks of nanostructures 22, 24 following the etching process for simplicity. In general, the etching process may be used to form any number of vertical stacks of nanostructures 22, 24 over the fins 32.

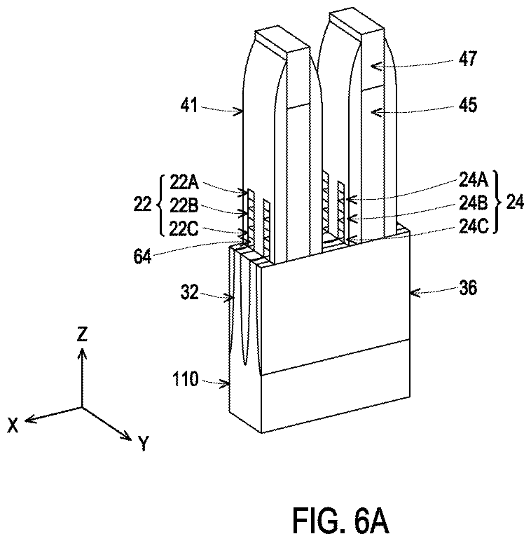

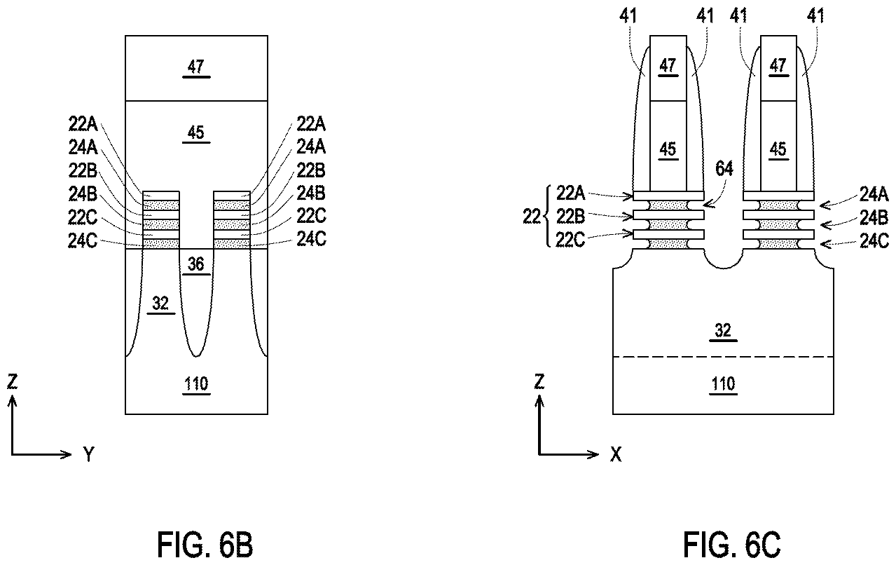

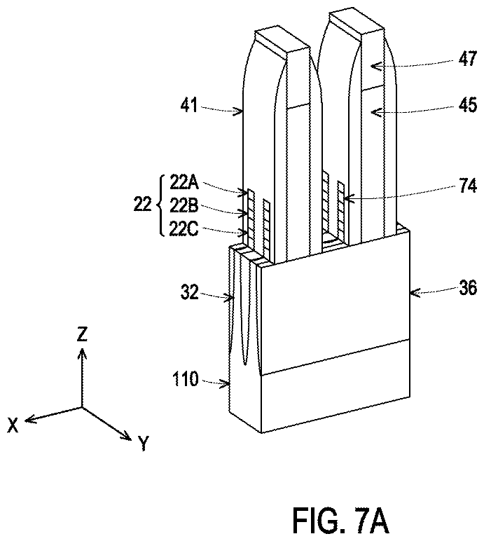

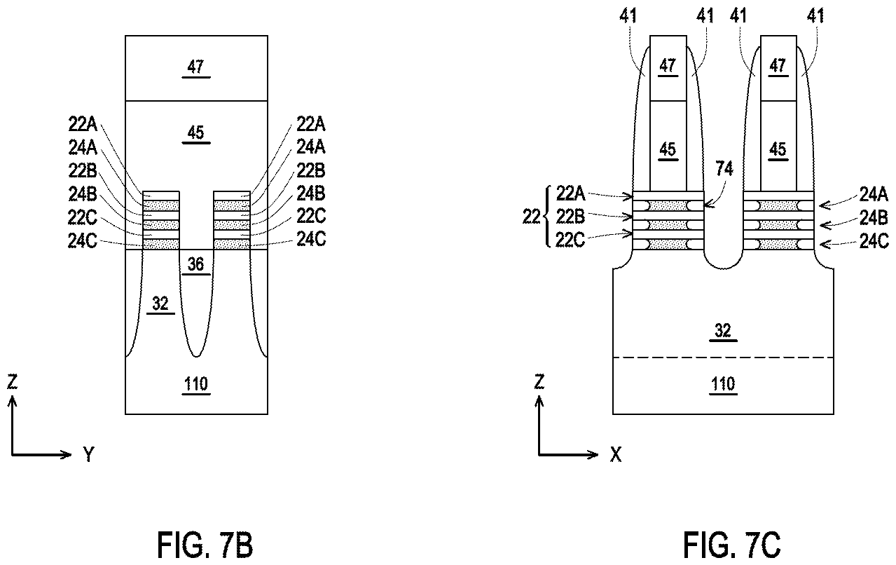

FIGS. 6A-6C and 7A-7C illustrate formation of inner spacers 74. A selective etching process is performed to recess end portions of the nanostructures 24 exposed by openings in the spacer layer 41 without substantially attacking the nanostructures 22. After the selective etching process, recesses 64 are formed in the nanostructures 24 at locations where the removed end portions used to be. The resulting structure is shown in FIGS. 6A-6C.

Next, an inner spacer layer is formed to fill the recesses 64 in the nanostructures 24 formed by the previous selective etching process. The inner spacer layer may be a suitable dielectric material, such as silicon carbon nitride (SiCN), silicon oxycarbonitride (SiOCN), or the like, formed by a suitable deposition method such as PVD, CVD, ALD, or the like. For example, an ALD may be performed to deposit a layer of SiN. An etching process, such as an anisotropic etching process, is performed to remove portions of the inner spacer layers disposed outside the recesses in the nanostructures 24. The remaining portions of the inner spacer layers (e.g., portions disposed inside the recesses 64 in the nanostructures 24) form the inner spacers 74. The resulting structure is shown in FIGS. 7A-7C. The inner spacers 74 may have the same or different width in the X-axis direction from each other. For example, as shown in FIGS. 7A-7C, the inner spacers 74 all have the same width. In some embodiments, due to tapering of the channels 22 following etching in FIGS. 5A-5C, the inner spacers 74 have substantially the same width, and the remaining portions of the nanostructures 24 have increasing width toward the substrate 110.

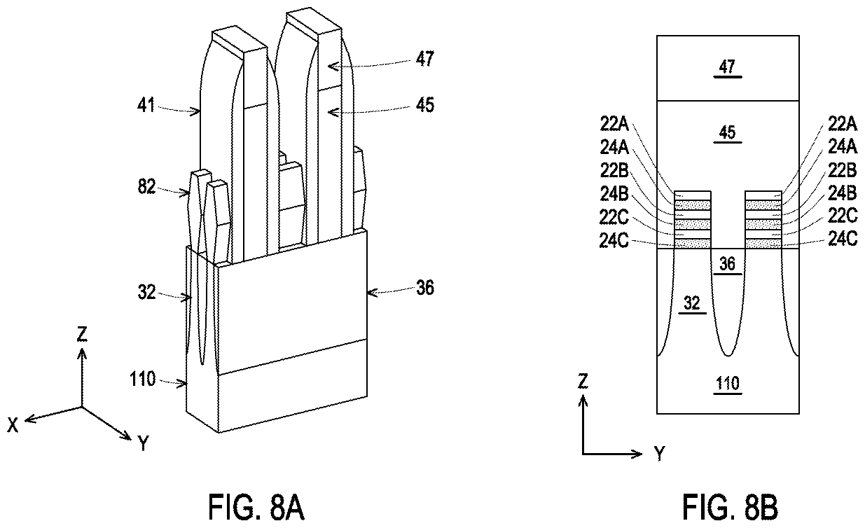

FIGS. 8A and 8B and 9A-13B illustrate formation of source/drain regions 82 corresponding to acts 1300, 1400, 1500 and 1600 of FIG. 20. In the illustrated embodiment, the source/drain regions 82 are epitaxially grown from epitaxial material(s). In some embodiments, the source/drain regions 82 exert stress in the respective channels 22A-22C, thereby improving performance. For example, as described with reference to FIGS. 1A and 1B and FIGS. 9A-13B, the source/drain regions 82 exert tensile stress in the respective channels 22A-22C that are N-type channels. The source/drain regions 82 are formed such that each dummy gate structure 40 is disposed between respective neighboring pairs of the source/drain regions 82. In some embodiments, the spacer layer 41 separates the source/drain regions 82 from the dummy gate layer 45 by an appropriate lateral distance to prevent electrical bridging to subsequently formed gates of the resulting device.

The source/drain regions 82 may include any acceptable material, such as appropriate for n-type or p-type devices. For n-type devices, the source/drain regions 82 include materials exerting a tensile strain in the channel regions, such as silicon, SiC, SiCP, SiP, or the like, in some embodiments. When p-type devices are formed, the source/drain regions 82 include materials exerting a compressive strain in the channel regions, such as SiGe, SiGeB, Ge, GeSn, or the like, in accordance with certain embodiments. The source/drain regions 82 may have surfaces raised from respective surfaces of the fins and may have facets. Neighboring source/drain regions 82 may merge in some embodiments to form a singular source/drain region 82 adjacent two neighboring fins 32.

The source/drain regions 82 may be implanted with dopants followed by an anneal. The source/drain regions may have an impurity concentration of between about 10¹⁹ cm⁻³ and about 10²¹ cm⁻³, or may be any of the dopant concentrations described with reference to FIGS. 1A and 1B. N-type and/or p-type impurities for source/drain regions 82 may be any of the impurities discussed with reference to previous figures. In some embodiments, the source/drain regions 82 are in situ doped during growth. A contact etch stop layer (CESL) 131 and interlayer dielectric (ILD) 130, shown in FIG. 16, may then be formed covering the dummy gate structures 40 and the source/drain regions 82. The CESL 131 and ILD 130 are omitted from FIGS. 8A-15C for simplicity of illustration.

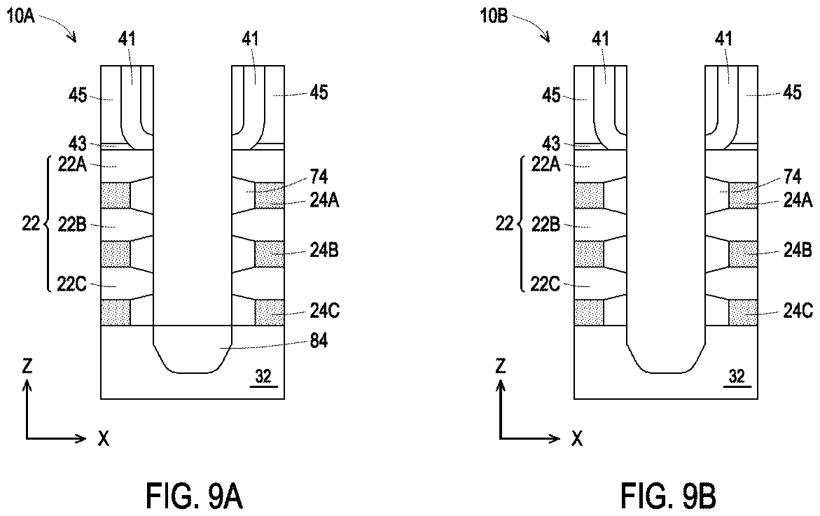

FIGS. 9A-13B are cross-sectional side views illustrating formation of the source/drain regions 82 in accordance with various embodiments. FIGS. 9A, 10A, 11A, 12A, 13A show the structure in which the liner layer 84 is included. FIGS. 9B, 10B, 11B, 12B, 13B show the structure in which the liner layers 84 are omitted.

In FIG. 9A, the liner layer 84 is formed, corresponding to optional act 1300 of FIG. 20. The liner layer 84 may be a silicon layer that is formed by a suitable growth operation. Following growth of the liner layer 84, the liner layer 84 may have an upper surface that is substantially coplanar with an upper surface of the fin 32. In some embodiments, the upper surface of the liner layer 84 is slightly above a bottom surface of the bottommost inner spacers 74. In some embodiments, the liner layer 84 is not formed, as shown in FIG. 9B.

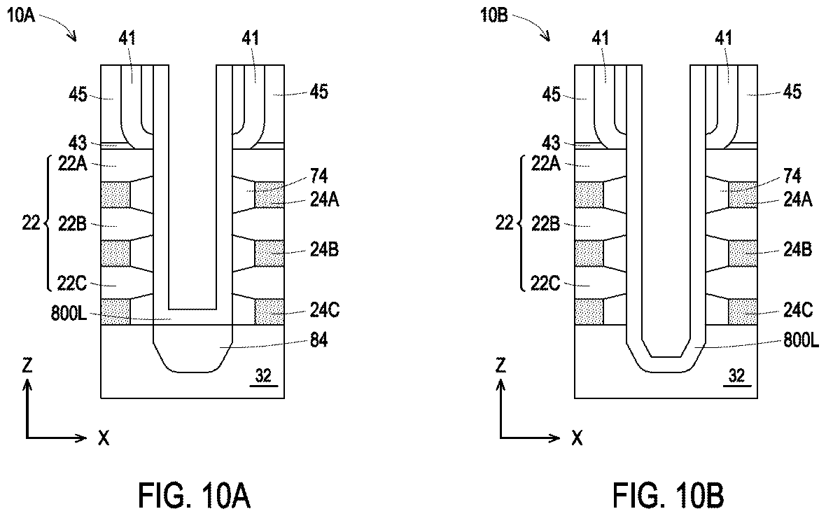

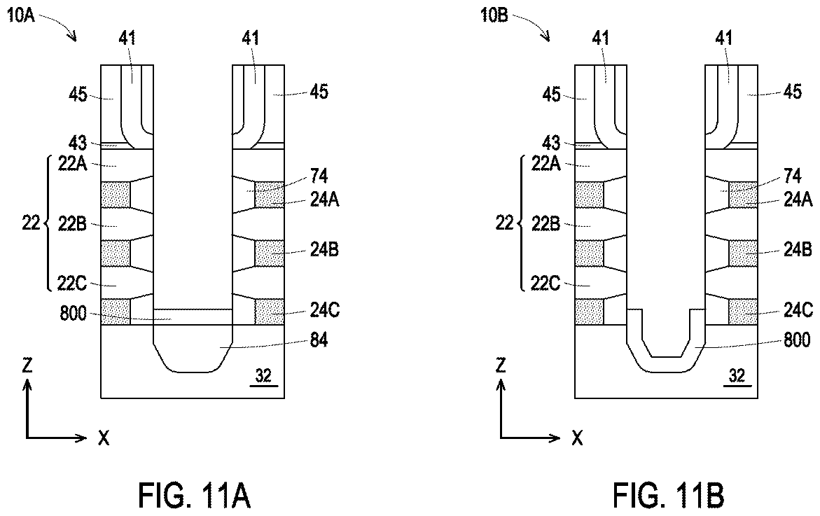

In FIGS. 10A, 10B, 11A and 11B, a bottom isolation structure 800 is formed in the source/drain trench 57, corresponding to act 1400 of FIG. 20. In FIGS. 10A and 10B, the bottom isolation layer 800L is provided at the bottom of the S/D trench 57. As such, the bottom SiGe:P or SiGe:As film formed in subsequent operations may be amorphous and removed during an etching process of a selective epitaxial growth process. The sidewall SiGe:P or SiGe:As of the source/drain region 82 becomes crystalline and remains on the sidewall. In FIG. 10A, the bottom isolation layer 800L is formed on exposed surfaces of the sidewall spacers 41, the channels 22, the inner spacers 74 and the liner layer 84. In FIG. 10B, the bottom isolation layer 800L is formed on exposed surfaces of the sidewall spacers 41, the channels 22, the inner spacers 74 and the fin 32. In FIGS. 10A and 10B, the bottom isolation layer 800L is formed by a suitable process, such as a plasma-enhanced ALD, and is or includes a dielectric material, such as SiN. The bottom isolation layer 800L may include SiN, SiCN, SiCON, SiOC, SiC, SiO or the like, and may be deposited to thickness of about 1-5 nm, or slightly thicker. Following the conformal film deposition process (e.g., PEALD), a film treatment (e.g., etching back) may be performed. The film deposition process may include a cyclic PEALD process with reaction gas of DCS and NH3/Ar plasma, and the film treatment (e.g., etching) may be implemented by Ar/N2 plasma. The resulting structure is shown in FIGS. 11A and 11B. Following the film treatment, the bottom isolation structure 800 may have thickness in a range of about 1 nm to about 5 nm, and shape that is a horizontal I-shape, a bowl shape, a dish shape, a U-shape, a V-shape or other suitable shape, which may conform to shape of the S/D trench 57 and optionally the liner layer 84 as selected by the S/D trench etching process described with reference to FIGS. 5A-5C.

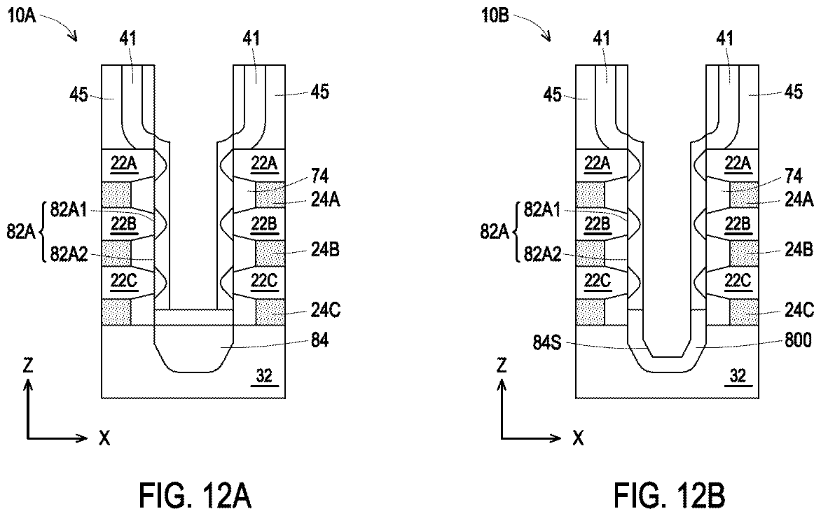

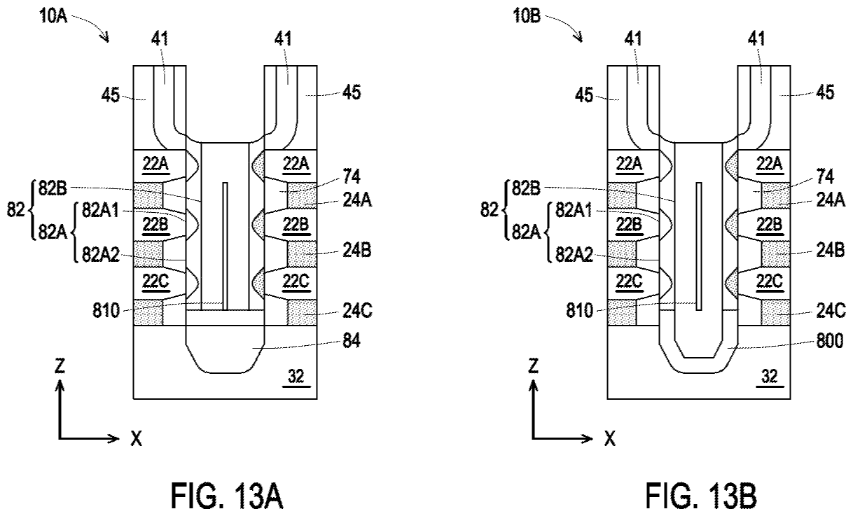

In FIGS. 12A, 12B, 13A and 13B, the source/drain region 82 is epitaxially grown in the S/D trench 57. In FIGS. 12A and 12B, the L1 layer 82A, which includes the first epitaxial sub-layers 82A1 and the second epitaxial sub-layers 82A2, is formed in the S/D trench 57, corresponding to act 1500 of FIG. 20. In FIGS. 13A and 13B, the L2 layer 82B is formed on the L1 layer 82A in the S/D trench 57, corresponding to act 1600 of FIG. 20.

In FIG. 12A, the liner layer 84 is disposed between the bottom isolation structure 800 and the substrate 110, the fin 32 or both. In FIG. 12B, the liner layer 84 is not present. Each of the first epitaxial sub-layers 82A1 and the second epitaxial sub-layer 82A2 may be a germanium-containing epitaxial layer for NMOS transistors that is formed in the S/D trench 57. Sequential compressive SiGe:P or SiGe:As deposition allows the epitaxial growth mechanism to be sidewall (SW) growth instead of bottom-up growth (e.g., growth that begins from the fin 32 or the substrate 110). The bottom isolation structure 800 is provided at the bottom of the S/D trench, so SiGe:P or SiGe:As film formed at the bottom of the S/D trench may become amorphous and be removed during an etching process of the selective epitaxial growth. Sidewall SiGe:P or SiGe:As becomes crystalline and remains on the sidewalls, e.g., the channels 22A-22B and the inner spacers 74. The germanium-containing epitaxial layers for NMOS may be formed by multiple selective epitaxial growth processes (or so-called “cyclic deposition and etching processes”), which may include deposition operations and etching operations performed alternately or simultaneously. For example, a first epitaxial growth process may be performed to form the first epitaxial sub-layers 82A1. The first epitaxial sub-layers 82A1 may grow outward from the channels 22. In some embodiments, the first epitaxial sub-layers 82A1 do not merge and are offset from each other in the X-axis direction and the Z-axis direction, as shown.

Following formation of the first epitaxial sub-layers 82A1, the second epitaxial sub-layer 82A2 may be formed by performing a second epitaxial growth process. In some embodiments, the first and second epitaxial growth processes are different, similar or the same. In some embodiments, the first and second epitaxial growth processes are different phases of a single, continuous growth process. In some embodiments, visible interfaces are present between the first and second epitaxial sub-layers 82A1, 82A2. In some embodiments, the first and second epitaxial sub-layers 82A1, 82A2 have the same or substantially the same Ge %, dopant atomic ratio and dopant concentration. In some embodiments, one or more of the Ge %, dopant atomic ratio and dopant concentration is different between the first and second epitaxial sub-layers 82A1, 82A2. The bottom isolation structure 800 is provided at the bottom of the S/D trench, so SiGe:P or SiGe:As film formed at the bottom of the S/D trench may become amorphous and be removed during an etching process of the selective epitaxial growth. As shown in FIG. 12B, for example, a surface 84S of the bottom isolation structure 800 may be substantially free of the L1 layer 82A following formation of the L1 layer 82A.

In FIGS. 13A, 13B, following formation of the L1 layer 82A, the L2 layer 82B is formed. A third epitaxial growth process may be performed to form the L2 layer 82B. In some embodiments, a seam 810 is formed during formation of the L2 layer 82B. The seam 810 may form due to merging at the upper portion of the L2 layer 82B before the middle portion thereof can merge. In some embodiments, the seam 810 is not present. The third epitaxial growth process may be similar in many respects to the first and second epitaxial growth processes, but may use different ratios of reaction gases and dopants, such that the L2 layer 82B is different from the L1 layer 82A. In the L1 and L2 layers 82A, 82B, germanium concentration or “Ge %” (e.g., Ge/Si atomic ratio) may be lower than about 70%, and Ge % (Ge/Si atomic ratio) of the L2 layer 82B is higher than Ge % (Ge/Si atomic ratio) of the L1 layer 82A. For example, the L1 layer 82A may have Ge % that may range from about 10% to about 50%, and the L2 layer 82B may have Ge % that may range from about 25% to about 70%.

Atomic ratio of N-type dopants (e.g., As or P) to Si in the L1 and L2 layers 82A, 82B may be lower than about 10%, and atomic ratio of N-type dopants in the L2 layer 82B may be higher than that in the L1 layer 82A. For example, atomic ratio of N-type dopants in the L1 layer 82A may range from about 0.5% to about 4%, and atomic ratio of N-type dopants in the L2 layer may range from about 0.5% to about 8%. In some embodiments, N-type dopant concentration in the L1 layer 82A is in a range of about 2.5E20 to about 2E21 cm⁻³, and N-type dopant concentration in the L2 layer 82B is in a range of about 2.5E20 to about 4E21 cm⁻³. Thickness of each of the L1 and L2 layers 82A, 82B may be less than about 15 nm, and thickness of the L1 layer 82A may be less than that of the L2 layer 82B.

As one non-limiting example, the L1 layer 82A may have Ge % of 15-50% and phosphide atomic ratio of 4-8%, and the L2 layer 82B may have Ge % of 25-50% and phosphide atomic ratio of 1-4%, and phosphide dopant concentration may be 5E20-2E21 cm⁻³. In another non-limiting example, the L1 layer 82A may have Ge % of 15-50% and arsenic atomic ratio of 2-6%, and the L2 layer 82B may have Ge % of 15-50% and arsenic atomic ratio of 0.5-6%, and arsenic dopant concentration may be 2.5E20-3E21 cm⁻³. Although two epitaxial layers 82A, 82B are illustrated in FIGS. 13A and 13B, number of the epitaxial layers is not limited thereto. In some embodiments, the number of the epitaxial layers in the source/drain region 82 can be three or more, or one.

For sidewall-dominated grown SiGe:P or SiGe:As epitaxial films, although the epitaxial films still generate a compressive stress, the SW grown SiGe:P or SiGe: As films can exert tensile strain on the Si nanosheets 22A-22C instead of compressive strain. In some embodiments, tensile strain is greater on the nanosheet 22B than on the nanosheets 22A, 22C. Namely, nanosheets 22A, 22C on the periphery (e.g., nearer the top or bottom) of a vertical stack may have lower tensile strain than nanosheet(s) 22B in the middle of the vertical stack. For example, a nanosheet(s) at the center of the vertical stack may have the highest tensile strain, and tensile strain may decrease with increased distance from the center, where the “center” refers to the center of the vertical stack along the Z-axis direction.

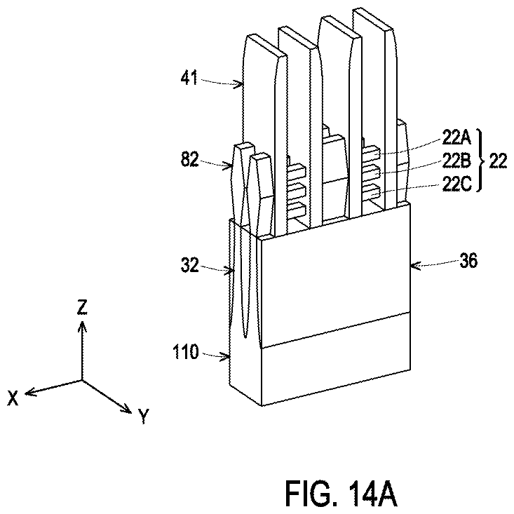

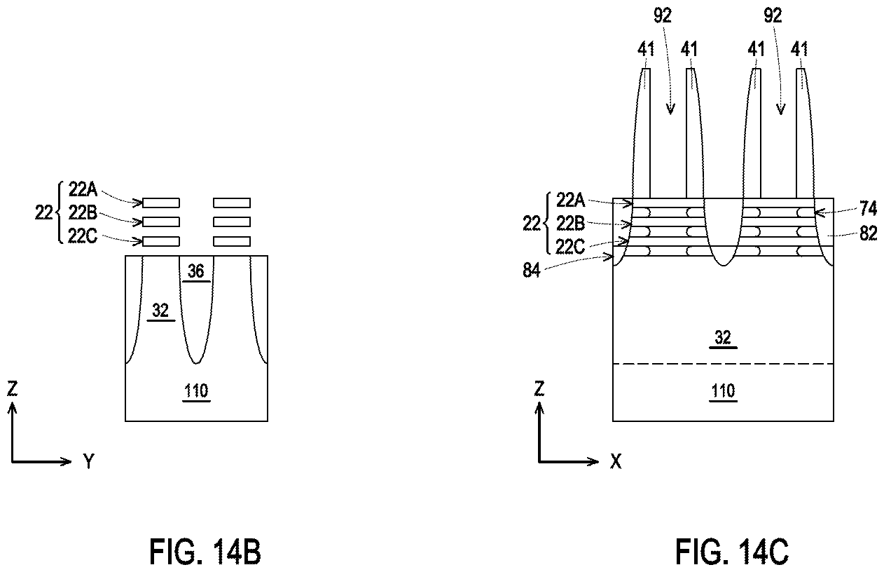

FIG. 14A, FIG. 14B, and FIG. 14C illustrate release of fin channels 22A-22C by removal of the nanostructures 24A-24C, the mask layer 47, and the dummy gate layer 45. A planarization process, such as a CMP, is performed to level the top surfaces of the dummy gate layer 45 and sidewall spacer layer 41. The planarization process may also remove the mask layer 47 (see FIG. 8A) on the dummy gate layer 45, and portions of the sidewall spacer layer 41 along sidewalls of the mask layer 47. Accordingly, the top surfaces of the dummy gate layer 45 are exposed.

Next, the dummy gate layer 45 is removed in an etching process, so that recesses 92 are formed. In some embodiments, the dummy gate layer 45 is removed by an anisotropic dry etch process. For example, the etching process may include a dry etch process using reaction gas(es) that selectively etch the dummy gate layer 45 without etching the spacer layer 41. The dummy gate dielectric, when present, may be used as an etch stop layer when the dummy gate layer 45 is etched. The dummy gate dielectric may then be removed after the removal of the dummy gate layer 45.

The nanostructures 24 are removed to release the nanostructures 22. After the nanostructures 24 are removed, the nanostructures 22 form a plurality of nanosheets that extend horizontally (e.g., parallel to a major upper surface of the substrate 110). The nanosheets may be collectively referred to as the channels 22 of the nanostructure devices 20A, 20B formed.

In some embodiments, the nanostructures 24 are removed by a selective etching process using an etchant that is selective to the material of the nanostructures 24, such that the nanostructures 24 are removed without substantially attacking the nanostructures 22. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like.

In some embodiments, the nanostructures 24 are removed and the nanostructures 22 are patterned to form channel regions of both PFETs and NFETs. However, in some embodiments the nanostructures 24 may be removed and the nanostructures 22 may be patterned to form channel regions of NFETs, and nanostructures 22 may be removed and the nanostructures 24 may be patterned to form channel regions of PFETs. In some embodiments, the nanostructures 22 may be removed and the nanostructures 24 may be patterned to form channel regions of NFETs, and the nanostructures 24 may be removed and the nanostructures 22 may be patterned to form channel regions of PFETs. In some embodiments, the nanostructures 22 may be removed and the nanostructures 24 may be patterned to form channel regions of both PFETs and NFETs.

In some embodiments, the nanosheets 22 are reshaped (e.g., thinned) by a further etching process to improve gate fill window. The reshaping may be performed by an isotropic etching process selective to the nanosheets 22. After reshaping, the nanosheets 22 may exhibit the dog bone shape in which middle portions of the nanosheets 22 are thinner than peripheral portions of the nanosheets 22 along the X direction.

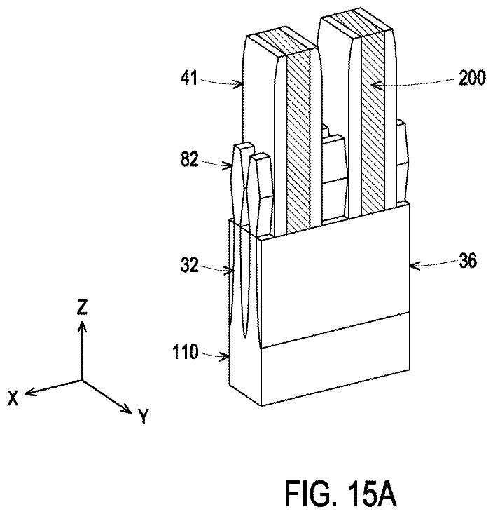

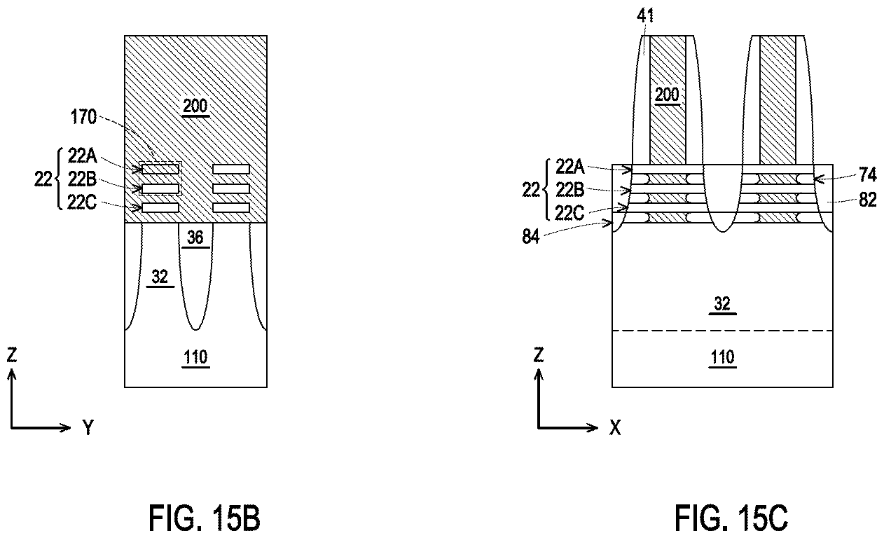

In FIGS. 15A-15C, replacement gates 200 are formed, corresponding to act 1700 of FIG. 20. The gate structure 200 generally includes the interfacial layer (IL, or “first IL”) 210, at least one gate dielectric layer 600, the work function metal layer 900, and the gate fill layer 290. In some embodiments, each replacement gate 200 further includes at least one of a second interfacial layer 240 or a work function barrier layer 700. Detailed structure and formation of the gate structure 200 are described with reference to FIG. 17. FIG. 16 shows the structure of FIG. 15C including the ILD 130 and the ESL 131. In some embodiments, the ESL 131 is formed following formation of the source/drain regions 82, and prior to removal of the sacrificial gate layer 45. The ILD 130 is formed on the ESL 131.

FIG. 17 is a detailed cross-sectional side view of the gate structure 200 in accordance with various embodiments. The gate structure 200 shown in FIG. 17 includes an interfacial layer 210, the gate dielectric layer 600, a second interfacial layer 240, a work function barrier layer 700, a work function tuning layer 900 and the core layer 290.

The interfacial layer 210, which may be an oxide of the material of the channels 22A-22C, is formed on exposed areas of the channels 22A-22C and the top surface of fins 32 when present. The interfacial layer 210 promotes adhesion of the gate dielectric layers 600 to the channels 22A-22C. In some embodiments, the interfacial layer 210 has thickness of about 5 Angstroms (A) to about 50 Angstroms (A). In some embodiments, the interfacial layer 210 has thickness of about 10 A. The interfacial layer 210 having thickness that is too thin may exhibit voids or insufficient adhesion properties. The interfacial layer 210 being too thick consumes gate fill window, which is related to threshold voltage tuning and resistance as described above. In some embodiments, the interfacial layer 210 is doped with a dipole, such as lanthanum, for threshold voltage tuning.

The gate dielectric layer 600 is positioned on the interfacial layer 210. In some embodiments, the gate dielectric layer 600 includes at least one high-k gate dielectric material, which may refer to dielectric materials having a high dielectric constant that is greater than a dielectric constant of silicon oxide (k≈3.9). Exemplary high-k dielectric materials include HfO₂, HfSiO, HfSiON, HfTaO, HfTiO, HfZrO, ZrO₂, Ta₂O₅, or combinations thereof. In some embodiments, the gate dielectric layer 600 has thickness of about 5 A to about 100 A. In some embodiments, the gate dielectric layer 600 may include a non-high-k dielectric material such as silicon oxide. In some embodiments, the gate dielectric layer 600 includes more than one high-k dielectric layer, of which at least one includes dopants, such as lanthanum, magnesium, yttrium, or the like, which may be driven in by an annealing process to modify threshold voltage of the nanostructure devices 20A, 20B.

In some embodiments, the gate dielectric layer 600 may include dopants, such as metal ions driven into the high-k gate dielectric from La₂O₃, MgO, Y₂O₃, TiO₂, Al₂O₃, Nb₂O₅, or the like, or boron ions driven in from B₂O₃, at a concentration to achieve threshold voltage tuning. As one example, for N-type transistor devices, lanthanum ions in higher concentration reduce the threshold voltage relative to layers with lower concentration or devoid of lanthanum ions, while the reverse is true for P-type devices. In some embodiments, the gate dielectric layer 600 of certain transistor devices (e.g., IO transistors) is devoid of the dopant that is present in certain other transistor devices (e.g., N-type core logic transistors or P-type IO transistors). In N-type IO transistors, for example, relatively high threshold voltage is desirable, such that it may be preferable for the IO transistor high-k dielectric layers to be free of lanthanum ions, which would otherwise reduce the threshold voltage.

The second IL 240 is formed on the gate dielectric layer 600, and the work function barrier layer 700 is formed on the second IL 240. The second IL 240 promotes better metal gate adhesion on the gate dielectric layer 600. In many embodiments, the second IL 240 further provides improved thermal stability for the gate structure 200, and serves to limit diffusion of metallic impurity from the work function metal layer 900 and/or the work function barrier layer 700 into the gate dielectric layer 600. In some embodiments, formation of the second IL 240 is accomplished by first depositing a high-k capping layer (not illustrated for simplicity) on the gate dielectric layer 600. The high-k capping layer comprises one or more of the following: HfSiON, HfTaO, HfTiO, HfTaO, HfAION, HfZrO, or other suitable materials, in various embodiments. In a specific embodiment, the high-k capping layer comprises titanium silicon nitride (TiSiN). In some embodiments, the high-k capping layer is deposited by an ALD using about 40 to about 100 cycles at a temperature of about 400 degrees C. to about 450 degrees C. A thermal anneal is then performed to form the second IL 240, which may be or comprise TiSiNO, in some embodiments. Following formation of the second IL 240 by thermal anneal, an atomic layer etch (ALE) with artificial intelligence (AI) control may be performed in cycles to remove the high-k capping layer while substantially not removing the second IL 240. Each cycle may include a first pulse of WCl₅, followed by an Ar purge, followed by a second pulse of O₂, followed by another Ar purge. The high-k capping layer is removed to increase gate fill window for further multiple threshold voltage tuning by metal gate patterning.

The work function barrier layer 700 is optionally included in the gate structure 200, in accordance with some embodiments. The work function barrier layer 700 is or comprises a metal nitride, such as TIN, WN, MON, TaN, or the like. In a specific embodiment, the work function barrier layer 700 is TiN. The work function barrier layer 700 may have thickness ranging from about 5 A to about 20 A. Inclusion of the work function barrier layer 700 provides additional threshold voltage tuning flexibility. In general, the work function barrier layer 700 increases the threshold voltage for NFET transistor devices, and decreases the threshold voltage (magnitude) for PFET transistor devices.

The work function metal layer 900, which may include one or more of an N-type work function metal layer, an in-situ capping layer, and an oxygen blocking layer, is formed on the work function barrier layer 700, in some embodiments. The N-type work function metal layer is or comprises an N-type metal material, such as TiAlC, TiAl, TaAlC, TaAl, or the like. The N-type work function metal layer may be formed by one or more deposition methods, such as CVD, PVD, ALD, plating, and/or other suitable methods, and has a thickness between about 10 A and 20 A. The in-situ capping layer is formed on the N-type work function metal layer. In some embodiments, the in-situ capping layer is or comprises TIN, TiSiN, TaN, or another suitable material, and has a thickness between about 10 A and 20 A. The oxygen blocking layer is formed on the in-situ capping layer to prevent oxygen diffusion into the N-type work function metal layer, which would cause an undesirable shift in the threshold voltage. The oxygen blocking layer is formed of a dielectric material that can stop oxygen from penetrating to the N-type work function metal layer, and may protect the N-type work function metal layer from further oxidation. The oxygen blocking layer may include an oxide of silicon, germanium, SiGe, or another suitable material. In some embodiments, the oxygen blocking layer is formed using ALD and has a thickness between about 10 A and about 20 A.

The metal fill layer 290 is positioned on the work function metal layer 900. In some embodiments, a glue layer (not separately illustrated) is formed between the oxygen blocking layer of the work function metal layer and the metal fill layer 290. The glue layer may promote and/or enhance the adhesion between the metal fill layer 290 and the work function metal layer 900. In some embodiments, the glue layer may be formed of a metal nitride, such as TiN, TaN, MON, WN, or another suitable material, using ALD. In some embodiments, thickness of the glue layer is between about 10 A and about 25 A. The metal fill layer 290 may be formed on the glue layer, and may include a conductive material such as tungsten, cobalt, ruthenium, iridium, molybdenum, copper, aluminum, or combinations thereof. In some embodiments, the metal fill layer 290 may be deposited using methods such as CVD, PVD, plating, and/or other suitable processes. Between the channels 22A-22C, the metal fill layer 290 is circumferentially surrounded (in the cross-sectional view) by the one or more work function metal layers 900, which are then circumferentially surrounded by the gate dielectric layers 600.

In some embodiments, a seam 510, which may be an air gap, is formed in the metal fill layer 290 vertically between the channels 22A, 22B. In some embodiments, the metal fill layer 290 is conformally deposited on the work function metal layer 900. The seam 510 may form due to sidewall deposited film merging during the conformal deposition. In some embodiments, the seam 510 is not present between the neighboring channels 22A, 22B.

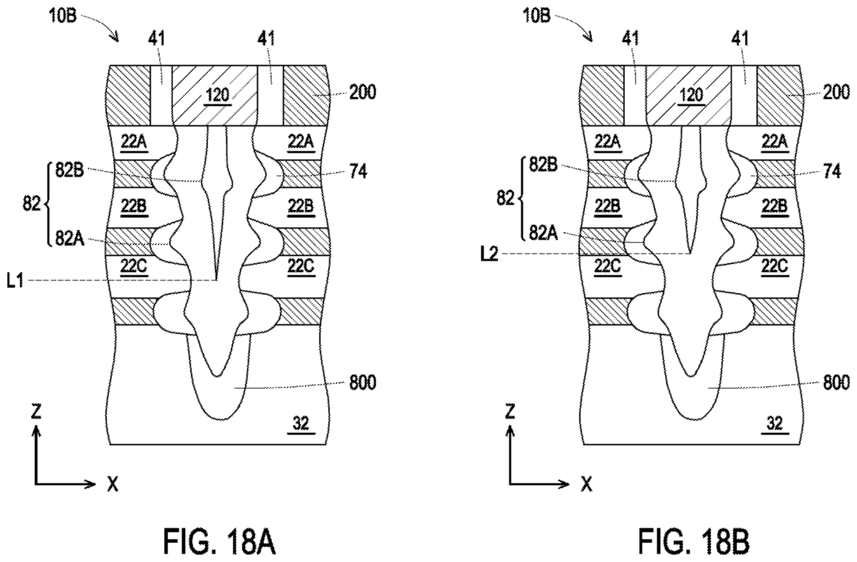

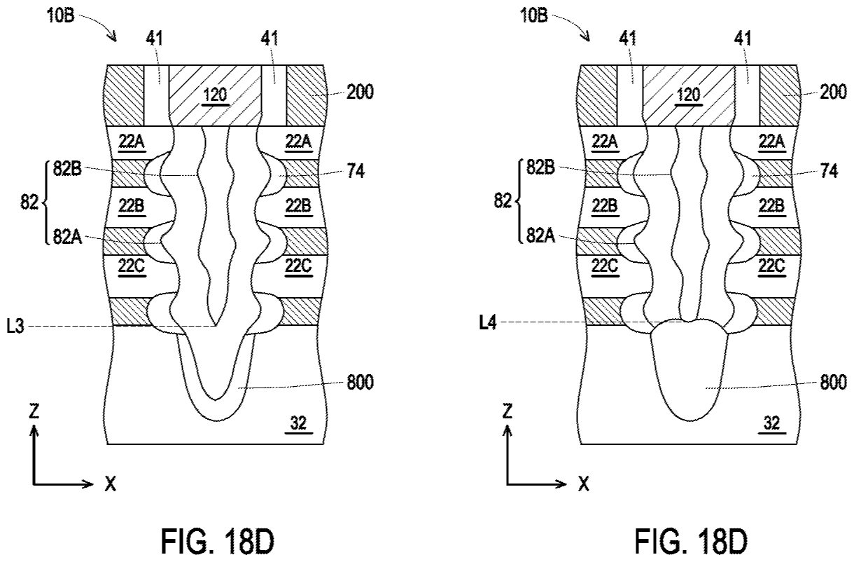

FIGS. 18A-18D are cross-sectional side view diagrams illustrating the device 10B in accordance with various embodiments. In the device 10B, the liner layer 84 is not present. In FIG. 18A, the L2 layer 82B extends from the bottom surface of the source/drain contact 120 to a depth L1 that is level with the bottommost channels 22C. In FIG. 18B, the L2 layer 82B extends from the bottom surface of the source/drain contact 120 to a depth L2 that is about level with an interface of an upper surface of the bottommost channel 22C and the gate structure 200 thereabove. In FIG. 18C, the L2 layer 82B extends from the bottom surface of the source/drain contact 120 to a depth L3 that is about level with the bottom surface of the gate structure 200 and slightly above a bottom surface of a bottommost inner spacer 74. In FIG. 18D, the bottom isolation structure 800 extends from the bottom of the S/D trench 57 to a level that is slightly above the bottom surface of the gate structure 200. The L2 layer 82B extends from the bottom surface of the source/drain contact 120 to the upper surface of the bottom isolation structure 800.

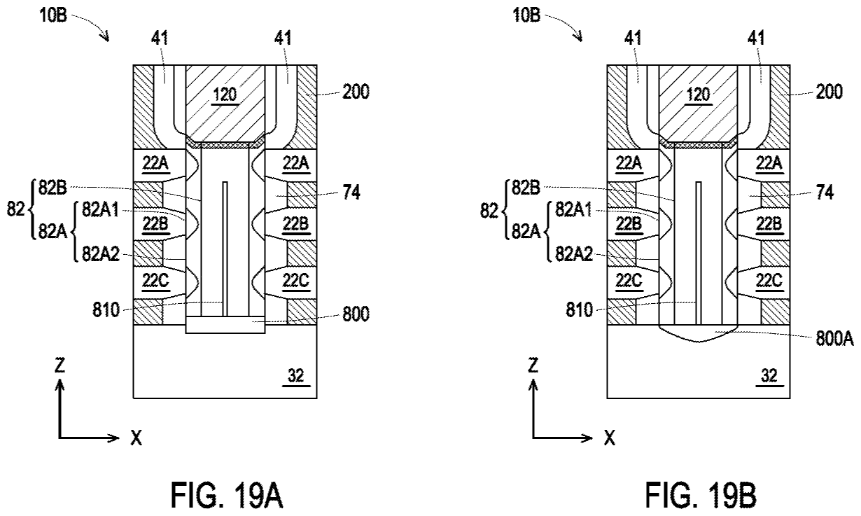

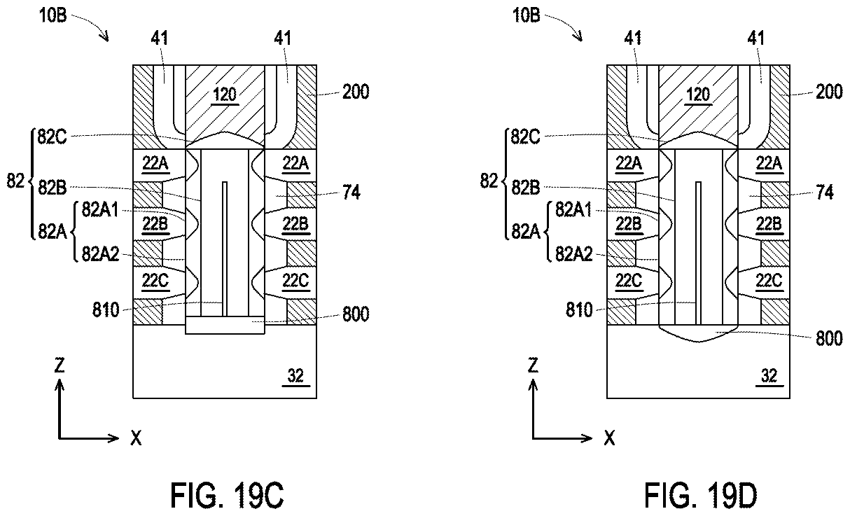

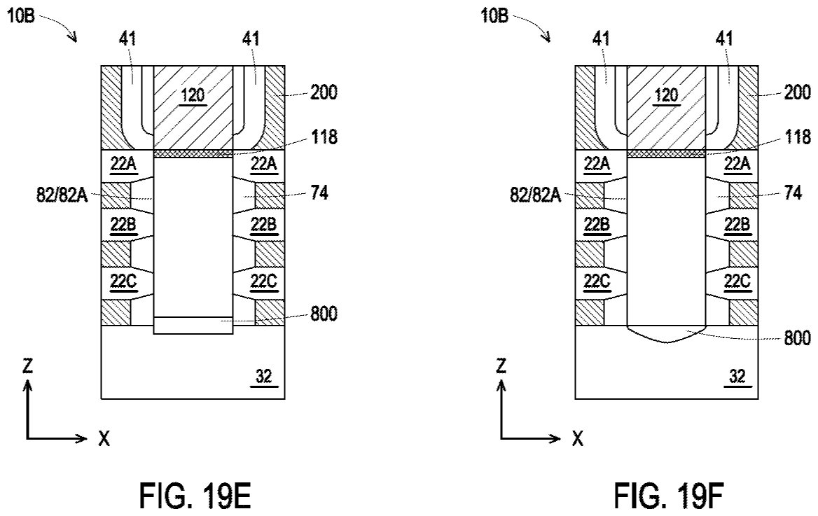

FIGS. 19A-19F illustrate the device 10B in accordance with various embodiments. In FIG. 19A, the bottom isolation structure 800 is a substantially horizontal thin film layer that extends from one inner spacer 74 (left side) to another inner spacer 74 (right side). The bottom isolation structure 800 has thickness in the Z-axis direction that is about 1-5 nm. In FIG. 19B, a bottom isolation structure 800A that is the same in most respects to the bottom isolation structure 800 has a triangular or convex profile, as shown. Thickness of the bottom isolation structure 800A may decrease toward a periphery of the bottom isolation structure 800A. The bottom isolation structure 800A may extend past the source/drain region 82 in the horizontal directions to provide isolation between the source/drain region 82 and the fin 32 and/or substrate 110. In some embodiments, the upper surface of the bottom isolation structure 800A is planar, concave, or another suitable shape. The seam 810 is shown in FIGS. 19A and 19B, but may not be present, for example, when the L2 layer 82B merges completely during growth thereof.

In FIGS. 19C and 19D, a third epitaxial or “L3” layer 82C is formed on upper surfaces of the L1 and L2 layers 82A, 82B. The L3 layer 82C may be formed by a fourth epitaxial growth process that is similar in many respects to the first, second and third epitaxial growth processes. In FIGS. 19C and 19D, the L1 layer 82A may have Ge % that may range from 10% to 50%, the L2 layer 82B may have Ge % that may range from 25% to 70%, and the L3 layer 82C may have Ge % that may range from 50% to 70%. N-type dopant in the L1 layer 82A may range from 0.5% to 4%, N-type dopant in the L2 layer 82B may range from 0.5% to 8%, and N-type dopant in the L3 layer 82C may range from 2% to 8%. N-type dopant concentration in the L1 layer 82A may range from 2.5E20 cm⁻³ to 2E21 cm⁻³, N-type dopant concentration in the L2 layer 82B may range from 2.5E20 cm⁻³ to 4E21 cm⁻³, and N-type dopant concentration in the L3 layer 82C may range from 1E21 cm⁻³ to 4E21 cm⁻³. The seam 810 is shown in FIGS. 19C and 19D, but may not be present in the device 10B including the L3 layer 82C in some embodiments.

In FIGS. 19E and 19F, only the L1 layer 82A is present in the source/drain region 82, as shown. As such, the source/drain region 82 may have uniform or substantially uniform Ge % concentration in a range from 25% to 70%, and average N-type dopant concentration in a range from 2E20 cm⁻³ to 5E20 cm⁻³.

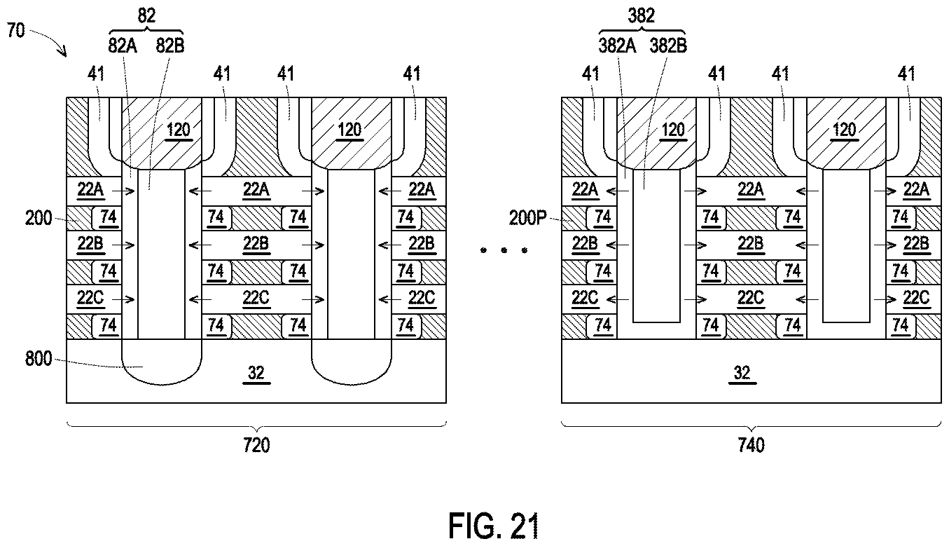

FIG. 21 is a cross-sectional side view of an IC device 70 in accordance with various embodiments. The IC device 70 may be a complementary MOS (CMOS) device, such as a portion of a memory cell (e.g., a static random access memory cell) that includes NFETs 720 and PFETs 740. The NFETs 720 may be similar to or the same as the device 10A or the device 10B. For example, as shown in FIG. 21, the NFETs 720 may be similar to the device 10B described with reference to FIG. 19B. As shown in FIG. 21, the source/drain regions 82 of the NFETs exert tensile strain (shown by arrows) on the channels 22. The PFETs 740 may be different from the NFETs in some respects. For example, the PFETs 740 include source/drain regions 382, that include L1 layer 382A and L2 layer 382B, and do not include a bottom isolation structure (e.g., the bottom isolation structure 800) between the source/drain regions 382 and the fin 32. As such, the L1 layer 382A may grow in a bottom-up manner instead of a sidewall-dominated manner, such that the L1 layer 382A is present on sidewalls of the channels 22 and inner spacers 74, and is also present on the upper surface of the fin 32. Because the L1 layer 382A is not grown in the sidewall-dominated manner, the source/drain regions 382 exert compressive strain on the channels 22 of the PFETs 740, which is advantageous to improve carrier mobility in the channels 22 of the PFETs 740.

In the PFETs 740, the L1 layer 382A has Ge % that may range from 10% to 35%, and the L2 layer 382B has Ge % that may range from 25% to 80%. P-type dopant in the L1 layer 382A may range from 0.5% to 4%, and P-type dopant in the L2 layer 382B may range from 1% to 8%. P-type dopant concentration in the L1 layer 382A may range from 2.5E20 cm⁻³ to 2E21 cm⁻³, and P-type dopant concentration in the L2 layer 382B may range from 3E20 cm⁻³ to 4E21 cm⁻³.

Embodiments may provide advantages. The bottom isolation structure 800 in the NFETs 10A, 10B promotes sidewall-dominated growth of the L1 and L2 layers 82A, 82B of the source/drain region 82, which results in tensile strain in the channels 22A-22C of the NFETs 10A, 10B. The tensile strain improves carrier mobility in the NFETs 10A, 10B. In CMOS devices, such as the device 70, the bottom isolation structure 800 may be omitted in the PFETs 740, which promotes bottom-up growth of the source/drain region 382, which results in compressive strain in the channels 22A-22C of the PFETs 740. The compressive strain improves carrier mobility in the PFETs 740.

In accordance with at least one embodiment, a device includes: a stack of nanostructure channels over a substrate; a gate structure wrapping around the stack; and a source/drain region on the substrate. The source/drain region includes: a first epitaxial layer in direct contact with the nanostructure channels; and a second epitaxial layer on the first epitaxial layer, the second epitaxial layer having higher germanium concentration than the first epitaxial layer. The device further includes a bottom isolation structure between the source/drain region and the substrate, the bottom isolation structure being a dielectric layer that is in direct contact with the source/drain region.

In accordance with at least one embodiment, a device includes: a semiconductor substrate; a first semiconductor channel over the semiconductor substrate; a second semiconductor channel over the first semiconductor channel; a gate structure wrapping around the first and second semiconductor channels; a first inner spacer abutting a lower surface of the second semiconductor channel, an upper surface of the first semiconductor channel and a first sidewall surface of the gate structure; a second inner spacer abutting a lower surface of the first semiconductor channel, an upper surface of the semiconductor substrate and a second sidewall surface of the gate structure; a recess in the semiconductor substrate; a liner layer in the recess, the liner layer having an upper surface that is substantially level with an upper surface of the semiconductor substrate, the liner layer being a same material as the semiconductor substrate; a bottom isolation structure on the liner layer and abutting a sidewall of the second inner spacer; and a source/drain region on the bottom isolation structure and physically isolated from the semiconductor substrate by the bottom isolation structure.

In accordance with at least one embodiment, a device includes: a substrate; an N-type transistor on the substrate, including: a first stack of first nanostructure channels; a bottom isolation structure; and a first source/drain region that is in direct contact with the first nanostructure channels and the bottom isolation structure, the first source/drain region being physically isolated from the substrate by the bottom isolation structure; and a P-type transistor on the substrate, including: a second stack of second nanostructure channels; and a second source/drain region that is in direct contact with the second nanostructure channels and the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a stack of nanostructure channels over a substrate;
a gate structure wrapping around the stack;
a source/drain region on the substrate, the source/drain region including:
a first epitaxial layer in direct contact with the channels; and
a second epitaxial layer on the first epitaxial layer, the second epitaxial layer having higher germanium concentration than the first epitaxial layer; and
a bottom isolation structure between the source/drain region and the substrate, the bottom isolation structure being a dielectric layer that is in direct contact with the source/drain region.

2. The device of claim 1, further comprising:
the substrate; and
a recess in the substrate underlying the bottom isolation structure;
wherein the source/drain region extends into the recess.

3. The device of claim 2, wherein the bottom isolation structure lines an upper surface of the recess and extends to a level above the recess.

4. The device of claim 3, wherein the bottom isolation structure has thickness in a range of about 1 nanometer (nm) to about 5 nm.

5. The device of claim 3, wherein the bottom isolation structure includes SiN, SiCN, SiCON, SiOC, SiC or SiO.

6. The device of claim 1, wherein the source/drain region further comprises a third epitaxial layer, the third epitaxial layer being in direct contact with upper surfaces of the first epitaxial layer and the second epitaxial layer, the third epitaxial layer extending to a level above an uppermost channel of the stack of nanostructure channels.

7. A device comprising:
a semiconductor substrate;
a first semiconductor channel over the substrate;
a second semiconductor channel over the first semiconductor channel;
a gate structure wrapping around the first and second semiconductor channels;
a first inner spacer abutting a lower surface of the second semiconductor channel, an upper surface of the first semiconductor channel and a first sidewall surface of the gate structure;
a second inner spacer abutting a lower surface of the first semiconductor channel, an upper surface of the substrate and a second sidewall surface of the gate structure;
a recess in the semiconductor substrate;
a liner layer in the recess, the liner layer having an upper surface that is substantially level with an upper surface of the substrate, the liner layer being a same material as the semiconductor substrate;
a bottom isolation structure on the liner layer and abutting a sidewall of the second inner spacer; and
a source/drain region on the bottom isolation structure and physically isolated from the semiconductor substrate by the bottom isolation structure.

8. The device of claim 7, wherein the source/drain region includes:
a first epitaxial layer having germanium concentration that is in a range of about 10% to about 50%; and
a second epitaxial layer having germanium concentration greater than that of the first epitaxial layer in a range of about 25% to about 70%.

9. The device of claim 7, wherein the source/drain region includes:
a first epitaxial layer having N-type dopant atomic ratio that is in a range of about 0.5% to about 4%; and
a second epitaxial layer having N-type dopant atomic ratio that is greater than that of the first epitaxial layer in a range of about 0.5% to about 8%.

10. The device of claim 7, wherein the source/drain region includes:
a first epitaxial layer having N-type dopant concentration that is in a range of about 2.5E20 cm-3 to about 2E21 cm-3; and
a second epitaxial layer having N-type dopant concentration that is greater than that of the first epitaxial layer in a range of about 2.5E20 cm-3 to about 4E21 cm-3.

11. The device of claim 7, wherein the source/drain region includes:
a first epitaxial layer having germanium concentration that is in a range of about 10% to about 50%; and
a second epitaxial layer having germanium concentration greater than that of the first epitaxial layer in a range of about 25% to about 70%; and
a third epitaxial layer on upper surfaces of the first epitaxial layer and the second epitaxial layer, the third epitaxial layer having germanium concentration in a range of about 50% to about 70%.

12. The device of claim 7, wherein the source/drain region includes:
a first epitaxial layer in direct contact with the first and second semiconductor channels;
a second epitaxial layer on the first epitaxial layer; and
a source/drain contact on the first and second epitaxial layers.

13. The device of claim 12, wherein the second epitaxial layer extends from a lower surface of the source/drain contact to a level that is above the first semiconductor channel.

14. A device, comprising:
a substrate;
an N-type transistor on the substrate, including:
a first stack of first nanostructure channels;
a bottom isolation structure; and
a first source/drain region that is in direct contact with the first nanostructure channels and the bottom isolation structure, the first source/drain region being physically isolated from the substrate by the bottom isolation structure; and
a P-type transistor on the substrate, including:
a second stack of second nanostructure channels; and
a second source/drain region that is in direct contact with the second nanostructure channels and the substrate.

15. The device of claim 14, wherein the N-type transistor further includes a liner layer between the substrate and the bottom isolation structure.

16. The device of claim 14, wherein the first source/drain region includes:
a first epitaxial layer in direct contact with the first nanostructure channels; and
a second epitaxial layer on the first epitaxial layer, the second epitaxial layer having higher germanium concentration than the first epitaxial layer.

17. The device of claim 16, wherein the first epitaxial layer includes:
a plurality of first epitaxial sub-layers, each being in direct contact with a respective one of the first nanostructure channels and isolated from others of the plurality of first epitaxial sub layers; and
a second epitaxial sub-layer on the plurality of first epitaxial sub-layers.

18. The device of claim 16, further comprising:
a third epitaxial layer on upper surfaces of the first epitaxial layer and the second epitaxial layer, the third epitaxial layer extending to a level above an upper surface of an uppermost first nanostructure channel of the first stack.

19. The device of claim 16, wherein the second source/drain region includes:
a third epitaxial layer in direct contact with the second nanostructure channels; and
a fourth epitaxial layer on the third epitaxial layer, the fourth epitaxial layer having higher germanium concentration than the third epitaxial layer.

20. The device of claim 19, wherein germanium concentration is:
in a range of about 10% to about 50% in the first epitaxial layer;
in a range of about 25% to about 70% in the second epitaxial layer;
in a range of about 10% to about 35% in the third epitaxial layer; and
in a range of about 25% to about 80% in the fourth epitaxial layer.
